(19) United States
(12) Patent Application Publication
(10) Pub. No.: US 2025/0107037 A1
(43) Pub. Date: Mar. 27, 2025

(54) LIQUID-COOLING DEVICE AND ELECTRONIC DEVICE

(71) Applicant: WISTRON CORP., New Taipei City (TW)

(72) Inventors: Wen Hua Zhang, New Taipei City (TW); Cheng Ying Wu, New Taipei City (TW); SHIH CHANG CHEN, New Taipei City (TW); kuo-hua Peng, New Taipei City (TW); CHIEN-JUNG CHIU, New Taipei City (TW)

(21) Appl. No.: 18/395,889

(22) Filed: Dec. 26, 2023

(30) Foreign Application Priority Data
Sep. 22, 2023 (TW) 112136309

(51) Int. Cl. H05K 7/20

(52) U.S. Cl. CPC H05K 7/20254; H05K 7/20263

(57) ABSTRACT

The disclosure provides a liquid-cooling device and an electronic device. The liquid-cooling device includes an accommodation housing and a liquid-cooling assembly. The accommodation housing has an accommodation structure. The liquid-cooling assembly includes at least one liquid-cooling heat exchanger, a cold plate and a tubing. The at least one liquid-cooling heat exchanger is located in the accommodation structure. The cold plate is covered on the accommodation housing and covers the accommodation structure. The tubing is connected to the at least one liquid-cooling heat exchanger and penetrates through the cold plate.

### CROSS-REFERENCE TO RELATED APPLICATIONS

This non-provisional application claims priority under 35 U.S.C. § 119(a) on Patent Application No(s). 112136309 filed in Taiwan, R.O.C. on Sep. 22, 2023, the entire contents of which are hereby incorporated by reference.

### TECHNICAL FIELD

The disclosure relates to a liquid-cooling device and an electronic device, more particularly to a liquid-cooling device and an electronic device that prevent liquid leakage.

### BACKGROUND

Recently, servers are widely applied by enterprises for various developed technologies related to the internet and telecommunication. Also, the server is applied in daily life, such as technologies related to finance, economy, online banking, online credit card, artificial intelligence (AI) and the like. To implement the aforementioned technologies, servers that can realize high-performance computing are required. For example, the AI technology should be implemented with servers including high-end processors for achieving the requirement of the high-performance computing. However, the high-end processors generate a large amount of heat. If such heat is accumulated in the server instead of being dissipated away from the server timely, the accumulated heat may reduce the performance of the server or even may cause the thermal shutdown of the server.

Conventionally, an open-loop liquid-cooling system is additionally disposed in the server to dissipate the heat generated by the high-end processors away from the server in a liquid-cooling manner. However, the liquid coolant may leak from the tubing of the liquid-cooling system in the server, regardless of an open-loop system or a closed-loop system. The leaked liquid coolant may adversely affect the operation of the electronic components in the server, or may even cause a short circuit between the electronic components.

### SUMMARY

The disclosure provides a liquid-cooling device and an electronic device to prevent the leakage of the liquid coolant in the server.

One embodiment of this disclosure provides a liquid-cooling device including an accommodation housing and a liquid-cooling assembly. The accommodation housing has an accommodation structure. The liquid-cooling assembly includes at least one liquid-cooling heat exchanger, a cold plate and a tubing. The at least one liquid-cooling heat exchanger is located in the accommodation structure. The cold plate is covered on the accommodation housing and covers the accommodation structure. The tubing is connected to the at least one liquid-cooling heat exchanger and penetrates through the cold plate.

Another embodiment of this disclosure provides an electronic device including an accommodation housing, an electronic assembly and a liquid-cooling assembly. The accommodation housing has an accommodation structure. The electronic assembly is located in the accommodation structure. The liquid-cooling assembly includes at least one liquid-cooling heat exchanger, a cold plate and a tubing. The at least one liquid-cooling heat exchanger is located in the accommodation structure and thermally coupled to the electronic assembly. The cold plate is covered on the accommodation housing and covers the accommodation structure. The tubing is connected to the at least one liquid-cooling heat exchanger and penetrates through the cold plate.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of an electronic device according to a first embodiment of the disclosure;

FIG. 2 is an exploded view of the electronic device in FIG. 1;

FIG. 3 is a cross-sectional view of the electronic device in FIG. 1;

FIG. 4 is a cross-sectional view of an electronic device according to a second embodiment of the disclosure; and

FIG. 5 is a perspective view showing that the electronic device in FIG. 1 is fixed to an outdoor pole.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

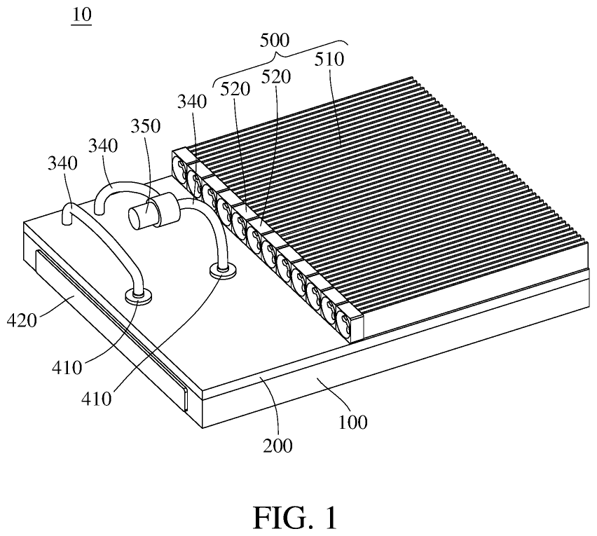

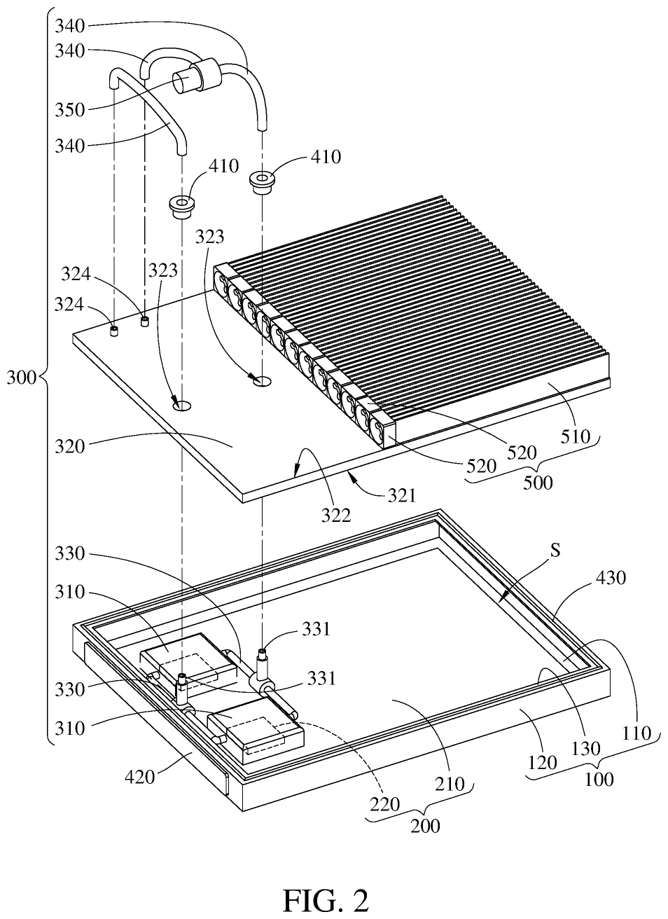

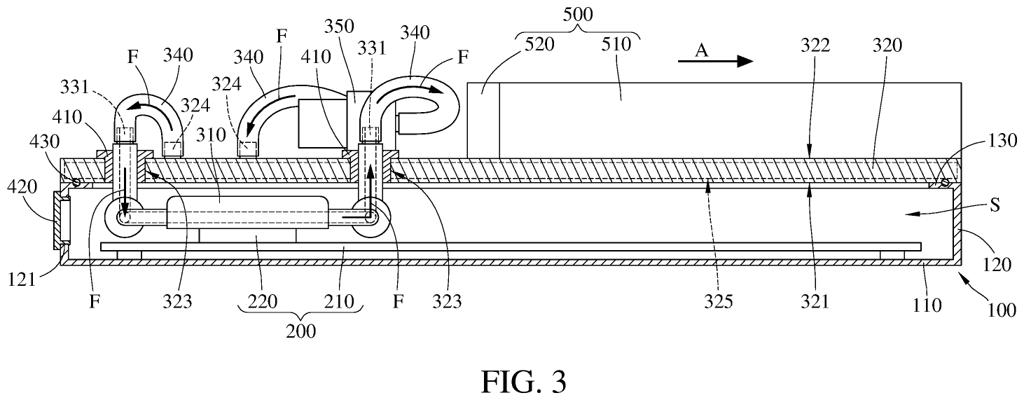

Please refer to FIGS. 1 to 3. FIG. 1 is a perspective view of an electronic device 10 according to a first embodiment of the disclosure. FIG. 2 is an exploded view of the electronic device 10 in FIG. 1. FIG. 3 is a cross-sectional view of the electronic device 10 in FIG. 1.

The electronic device 10 of this embodiment includes an accommodation housing 100, an electronic assembly 200 and a liquid-cooling assembly 300. The accommodation housing 100 and the liquid-cooling assembly 300 together configure, for example, a liquid-cooling device. The accommodation housing 100 includes a bottom plate 110, a peripheral side plate 120 and a peripheral top plate 130. The peripheral side plate 120 is connected to the bottom plate 110. The bottom plate 110 and the peripheral side plate 120 together form an accommodation structure S. The peripheral top plate 130 is connected to a side of the peripheral side plate 120 that is located farthest away from the bottom plate 110. The peripheral top plate 130 covers, for example, a part of the accommodation structure S. Further, the peripheral side plate 120 of the accommodation housing 100 further has an opening 121 connected to the accommodation structure S. The opening 121 is configured to expose a connector (not shown) of the electronic assembly 200 that is connected to external electronic components.

The electronic assembly 200 is located in the accommodation structure S. The electronic assembly 200 includes, for example, a motherboard 210 and a plurality of heat sources 220. The heat sources 220 are, for example, central processing units (CPUs) or graphic processing units (GPUs). The heat sources 220 are disposed on the motherboard 210. There is, for example, one motherboard 210 in this embodiment, but the disclosure is not limited thereto. In other embodiments, there may be a plurality of motherboards.

The liquid-cooling assembly 300 includes a plurality of liquid-cooling heat exchangers 310, a cold plate 320 and a tubing. In addition, the liquid-cooling assembly 300 may further include a pump 350. The liquid-cooling heat exchangers 310 are, for example, water blocks. The liquid-cooling heat exchangers 310 are located in the accommodation structure S, and are thermally coupled to the heat sources 220 of the electronic assembly 200. The quantity of the liquid-cooling heat exchangers 310 is adjusted based on, for example, the quantity of the heat sources 220. For example, if there are three heat sources 220, there will be three liquid-cooling heat exchangers 310 correspondingly.

The cold plate 320 is bonded to the accommodation housing 100 by, for example, screwing. The cold plate 320 is covered on the accommodation housing 100 to cover the accommodation structure S. The cold plate 320 has a first surface 321, a second surface 322 and two through holes 323. The second surface 322 faces away from the first surface 321, and the two through holes 323 penetrate through the first surface 321 and the second surface 322. In addition, the cold plate 320 has two first joints 324 and an inner channel 325, and the two first joints 324 are in fluid communication with each other via the inner channel 325 of the cold plate 320. The inner channel 325 of the cold plate 320 forms, for example, a pulsating loop or a thermosiphon loop.

The tubing includes, for example, two first connection tubes 330 and a plurality of second connection tubes 340. The two first connection tubes 330 are, for example, metal tubes. The two first connection tubes 330 and the liquid-cooling heat exchangers 310 are formed as a single piece by a bonding method such as welding or soldering. Thus, the pressure resistance at the position where the first connection tubes 330 and the liquid-cooling heat exchanger 310 are connected is improved. The two first connection tubes 330 are disposed through the two through holes 323, respectively. The two first connection tubes 330 each have a second joint 331, and the two second joints 331 are located outside the accommodation structure S. The second connection tubes 340 are, for example, hoses. The second connection tubes 340 connect the two first joints 324 and the two second joints 331. The pump 350 is connected to one of the two second connection tubes 340 so as to drive a conductive liquid coolant to form a cooling circulation between the liquid-cooling heat exchanger 310 and the cold plate 320. For example, the conductive liquid coolant flows along a direction F.

In this embodiment, there are, for example, two first connection tubes 330 and three second connection tubes 340 in the tubing, but the disclosure is not limited thereto. In other embodiments, there may be one first connection tube or at least three first connection tubes and two or at least four second connection tubes in the tubing.

In this embodiment, the liquid-cooling device may further include two first sealing components 410. The two first sealing components 410 are respectively sleeved on the two first connection tubes 330 and respectively inserted into the two through holes 323. Accordingly, liquid outside the accommodation structure S is prevented from flowing into the accommodation structure S via the through holes 323.

In this embodiment, the liquid-cooling device may further include a second sealing component 420. The second sealing component 420 presses against the I/O panel and covers the opening 121. Therefore, the transmission of electronic signals is enabled by the the power component (e.g., cable) disposed through the opening 121 while liquid outside the accommodation structure S is prevented from flowing into the accommodation structure S via the opening 121.

In this embodiment, the liquid-cooling device may further include a third sealing component 430. The third sealing component 430 is clamped between the peripheral top plate 130 and the cold plate 320. Thus, liquid outside the accommodation structure S is prevented from flowing into the accommodation structure S via a gap between the peripheral top plate 130 and the cold plate 320.

In this embodiment, the liquid-cooling device may further include an air-cooling assembly 500. The air-cooling assembly 500 is in thermal contact with the second surface 322 of the cold plate 320.

In this embodiment, the air-cooling assembly 500 includes a fin assembly 510 and a plurality of fans 520. The fin assembly 510 is thermally coupled to the second surface 322 of the cold plate 320. The fin assembly 510 are, for example, skived fins. The fin assembly 510 and the cold plate 320 are integrally formed as a single piece on the second surface 322. The fans 520 are disposed at a side of the fin assembly 510 so as to blow an airflow towards the fin assembly 510 along a direction A or blow an airflow along a direction opposite to the direction A.

In this embodiment, the fin assembly 510 are, for example, skived fins, but the disclosure is not limited thereto. In other embodiments, the fin assembly may be aluminum extruded fins or zipper fins.

In this embodiment, the fin assembly 510 is located over a part of the cold plate 320, but the disclosure is not limited thereto. In other embodiments, the fin assembly may be located over an entire of the cold plate 320.

In this embodiment, the liquid-cooling device actively drives the conductive liquid coolant by the pump 350, but the disclosure is not limited thereto. In other embodiments, if the conductive liquid coolant can passively circulate in the inner channel of the cold plate by, for example, thermosiphon, the liquid-cooling device may not include the pump.

The liquid-cooling device in the accommodation structure S are formed as a single piece with other components by a bonding method such as welding or soldering, and the first joints 324 and the second joints 331 of the liquid-cooling device that is assembled to the hose are located outside the accommodation structure S. Thus, even though leakage occurs at the first joints 324 and the second joints 331 of the liquid-cooling device due to high pressure, the leaked liquid is still prevented from directly flowing into the accommodation structure S.

In addition, the opening 121 of the accommodation housing 100 and the through holes 323 of the cold plate 320 that are connected to the accommodation structure S, as well as the gap between the cold plate 320 and the accommodation housing 100, are sealed by sealing components. Thus, the accommodation structure S may be regarded as a liquid-tight space. In this way, even though leakage occurs at the first joints 324 and the second joints 331, the electronic assembly 200 in the accommodation structure S is still prevented from being damaged.

In addition, in the electronic device 10 of this embodiment, the cold plate 320, the air-cooling assembly 500 and the second connection tubes 340 may be assembled into an assembly, and thus they can easily be mounted on or removed from the accommodation housing 100 and the first connection tubes 330. Accordingly, the configuration of the assembly of the cold plates 320, the air-cooling assembly 500 and the second connection tubes 340 may be easily adjusted according to actual requirements.

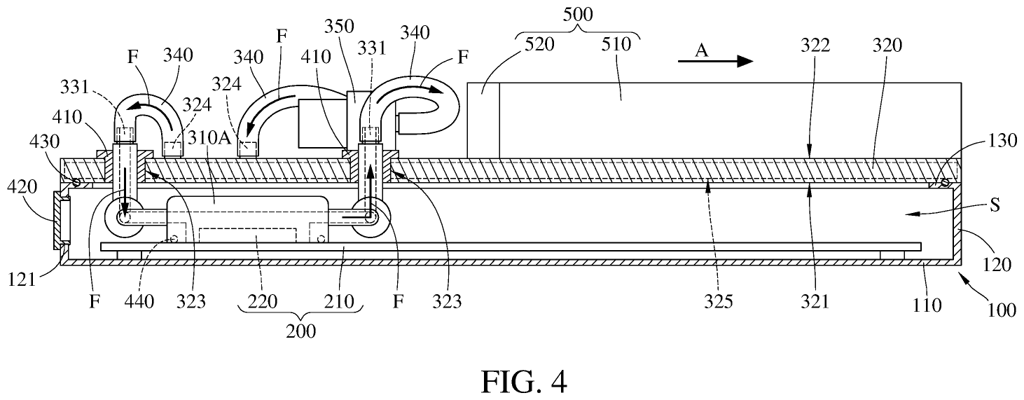

Please refer to FIG. 4. FIG. 4 is a cross-sectional view of an electronic device according to a second embodiment of the disclosure. In this embodiment, for example, a non-conductive liquid coolant is adopted in the liquid-cooling device. The liquid-cooling heat exchanger 310A is stacked on the motherboard 210. The liquid-cooling heat exchanger 310A and the motherboard 210 together surround the heat sources 220. The liquid-cooling device may further include a fourth sealing component 440. The fourth sealing component 440 is clamped between the liquid-cooling heat exchanger 310A and the motherboard 210. Thus, the liquid-cooling heat exchanger 310 and the motherboard 210 together surround the non-conductive liquid coolant and the heat sources 220, and fluid inside the liquid-cooling heat exchanger 310 is prevented from leaking to the accommodation structure S. Since the liquid-cooling heat exchanger 310 and the motherboard 210 together surround the non-conductive liquid coolant and the heat sources 220, the heat sources 220 is soaked or immersed in the non-conductive liquid coolant so as to improve the efficiency for the liquid-cooling device to cool the heat sources 220.

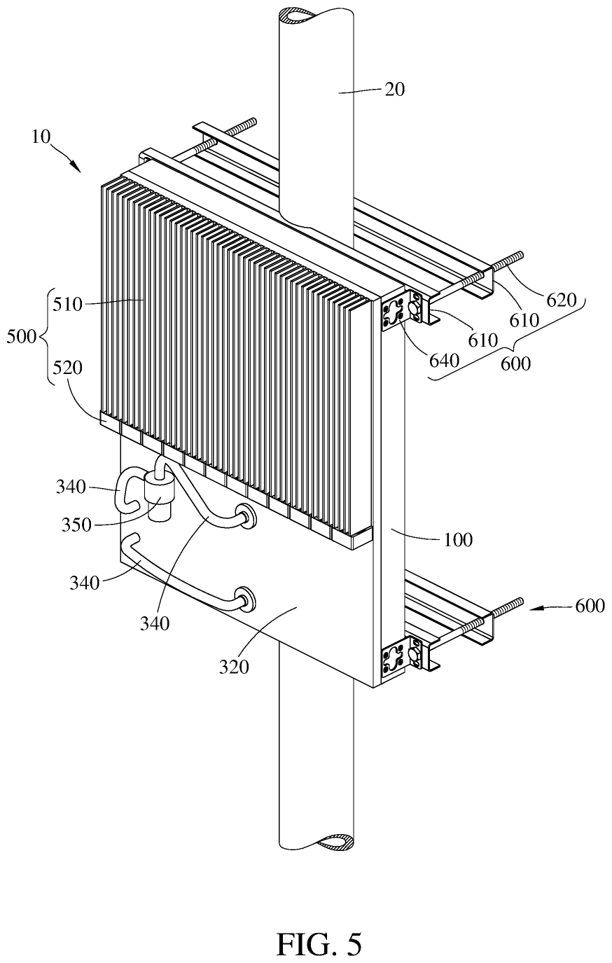

Please refer to FIG. 5. FIG. 5 is a perspective view showing that the electronic device 10 in FIG. 1 is fixed to an outdoor pole 20.

The electronic device 10 is fixed to the outdoor pole 20 via, for example, two fixing mechanisms 600. In detail, each fixing mechanism 600 includes two clamps 610, two connecting rods 620 and two mounting brackets 640. The two clamps 610 are movably disposed on the two connecting rods 620, and is guided by two connecting rods 620 to move towards or away from each other. The two mounting brackets 640 are disposed on one of the two clamps 610 and the accommodation housing 100. Thus, the accommodation housing 100 is fixed to the outdoor pole 20 or fixed on a position adjacent to a bottom side or a lateral side of an antenna (not shown).

According to the liquid-cooling device and the electronic device disclosed by above embodiments, the liquid-cooling device in the accommodation structure are formed as a single piece with other components by a bonding method such as welding or soldering, and the first joints and the second joints of the liquid-cooling device that is assembled to the hose are located outside the accommodation structure. Thus, even though leakage occurs at the first joints and the second joints of the liquid-cooling device due to high pressure, the leaked liquid is still prevented from directly flowing into the accommodation structure.

In addition, the opening of the accommodation housing and the through holes of the cold plate that are connected to the accommodation structure, as well as the gap between the cold plate and the accommodation housing, are sealed by sealing components. Thus, the accommodation structure may be regarded as a liquid-tight space. In this way, even though leakage occurs at the first joints and the second joints, the electronic assembly in the accommodation structure is still prevented from being damaged.

In addition, in the electronic device of this embodiment, the cold plate, the air-cooling assembly and the second connection tubes may be assembled into an assembly, and thus they can easily be mounted on or removed from the accommodation housing and the first connection tubes. Accordingly, the configuration of the assembly of the cold plates, the air-cooling assembly and the second connection tubes may be easily adjusted according to actual requirements.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A liquid-cooling device, comprising:
an accommodation housing, having an accommodation structure; and
a liquid-cooling assembly, comprising:
at least one liquid-cooling heat exchanger, located in the accommodation structure;
a cold plate, covered on the accommodation housing and covering the accommodation structure; and
a tubing, connected to the at least one liquid-cooling heat exchanger and penetrating through the cold plate.

2. The liquid-cooling device according to claim 1, wherein the cold plate has at least two through holes and two first joints, the tubing comprises at least two first connection tubes and a plurality of second connection tubes, the at least two first connection tubes are connected to the liquid-cooling heat exchanger and respectively disposed through the at least two through holes, the at least two first connection tubes each have a second joint, the two second joints are located outside the accommodation structure, and the plurality of second connection tubes connect the two first joints and the two second joints.

3. The liquid-cooling device according to claim 2, wherein the at least two first connection tubes and the liquid-cooling heat exchanger are formed as a single piece.

4. The liquid-cooling device according to claim 3, wherein the at least two first connection tubes are welded or soldered to the liquid-cooling heat exchanger.

5. The liquid-cooling device according to claim 2, further comprising at least two first sealing components, wherein the at least two first sealing components are respectively sleeved on the at least two first connection tubes and respectively inserted into the at least two through holes.

6. The liquid-cooling device according to claim 5, further comprising a second sealing component, wherein the accommodation housing has an opening, and the second sealing component covers the opening.

7. The liquid-cooling device according to claim 2, wherein the liquid-cooling assembly further comprises a pump connected to one of the plurality of second connection tubes.

8. The liquid-cooling device according to claim 2, further comprising an air-cooling assembly, wherein the cold plate has a first surface and a second surface facing away from each other, the second surface faces away from the accommodation housing, the at least two through holes penetrate through the first surface and the second surface, and the air-cooling assembly is in thermal contact with the second surface of the cold plate.

9. The liquid-cooling device according to claim 8, wherein the air-cooling assembly comprises a fin assembly thermally coupled to the second surface of the cold plate.

10. The liquid-cooling device according to claim 9, wherein the fin assembly and the cold plate are integrally formed as a single piece on the second surface.

11. The liquid-cooling device according to claim 9, wherein the air-cooling assembly further comprises at least one fan disposed at a side of the fin assembly.

12. The liquid-cooling device according to claim 6, further comprising a third sealing component, wherein the accommodation housing comprises a bottom plate, a peripheral side plate and a peripheral top plate, the peripheral side plate is connected to the bottom plate, the peripheral side plate and the bottom plate together form the accommodation structure, the peripheral top plate is connected to a side of the peripheral side plate that is located farthest away from the bottom plate, and the third sealing component is clamped between the peripheral top plate and the cold plate.

13. An electronic device, comprising:
an accommodation housing, having an accommodation structure;
an electronic assembly, located in the accommodation structure; and
a liquid-cooling assembly, comprising:
at least one liquid-cooling heat exchanger, located in the accommodation structure and thermally coupled to the electronic assembly;
a cold plate, covered on the accommodation housing and covering the accommodation structure; and
a tubing, connected to the at least one liquid-cooling heat exchanger and penetrating through the cold plate.

14. The electronic device according to claim 13, wherein the cold plate has at least two through holes and two first joints, the tubing comprises at least two first connection tubes and a plurality of second connection tubes, the at least two first connection tubes are connected to the liquid-cooling heat exchanger, and respectively disposed through the at least two through holes, the at least two first connection tubes each have a second joint, the two second joints are located outside the accommodation structure, and the plurality of second connection tubes connect the two first joints and the two second joints.

15. The electronic device according to claim 14, wherein the at least two first connection tubes and the liquid-cooling heat exchanger are formed as a single piece.

16. The electronic device according to claim 15, wherein the at least two first connection tubes are welded or soldered to the liquid-cooling heat exchanger.

17. The electronic device according to claim 14, wherein the liquid-cooling device further comprises at least two first sealing components, and the at least two first sealing components are respectively sleeved on the at least two first connection tubes and respectively inserted into the at least two through holes.

18. The electronic device according to claim 17, wherein the liquid-cooling device further comprises a second sealing component, the accommodation housing has an opening, and the second sealing component covers the opening.

19. The electronic device according to claim 14, wherein the liquid-cooling assembly further comprises a pump connected to one of the plurality of second connection tubes.

20. The electronic device according to claim 14, wherein the liquid-cooling device further comprises an air-cooling assembly, the cold plate has a first surface and a second surface facing away from each other, the second surface faces away from the accommodation housing, the at least two through holes penetrate through the first surface and the second surface, and the air-cooling assembly is in thermal contact with the second surface of the cold plate.

21. The electronic device according to claim 20, wherein the air-cooling assembly comprises a fin assembly thermally coupled to the second surface of the cold plate.

22. The electronic device according to claim 21, wherein the fin assembly and the cold plate are integrally formed as a single piece on the second surface.

23. The electronic device according to claim 18, wherein the liquid-cooling device further comprises a third sealing component, the accommodation housing comprises a bottom plate, a peripheral side plate and a peripheral top plate, the peripheral side plate is connected to the bottom plate, the peripheral side plate and the bottom plate together form the accommodation structure, the peripheral top plate is connected to a side of the peripheral side plate that is located farthest away from the bottom plate, and the third sealing component is clamped between the peripheral top plate and the cold plate.

24. The electronic device according to claim 23, wherein the liquid-cooling device further comprises a fourth sealing component, the electronic assembly comprises a motherboard and at least one heat source, the at least one heat source is disposed on the motherboard, the fourth sealing component is clamped between the liquid-cooling heat exchanger and the motherboard, and the liquid-cooling heat exchanger and the motherboard together surround the at least one heat source.
